(19) United States
(12) Patent Application Publication
(10) Pub. No.: US 2006/0054964 A1
(43) Pub. Date: Mar. 16, 2006

(54) Semiconductor device and method for fabricating a region thereon

(76) Inventors: Mark Isler, Dresden (DE); Jan-Malte Schley, Dresden (DE); Jens-Uwe Sachse, Dresden (DE); Pascal Deconinck, Dresden (DE); Ricardo Mikalo, Waltersdorf (DE)

Correspondence Address: SLATER & MATSIL LLP, 17950 PRESTON ROAD, SUITE 1000, DALLAS, TX, 75252, US

(21) Appl. No.: 10/941,752

(22) Filed: Sep. 15, 2004

(51) Int. Cl. H01L 29/76

(52) U.S. Cl. 257/314

(57) ABSTRACT

A semiconductor device comprises a transistor body of boron doped semiconductor substrate and a conterminous isolating area formed of insulating material, wherein an oxy-nitride layer is between the transistor body and the isolating area. This invention can be used in a transistor body for example in an NROM cell.

### TECHNICAL FIELD

The present invention generally relates to a semiconductor device and more particularly to a semiconductor device with a transistor body conterminous to an isolating area.

### BACKGROUND

A nitride read only memory (NROM) cell, as described in U.S. Pat. No. 5,768,192 or Boaz Eitan et.al.:“NROM: A Novel Localized Trapping, 2-Bit Nonvolatile Memory Cell”, IEEE Electron Device Letters, vol. 21, no. 11, November 2000, consists of a transistor body forming a channel between two diffusion areas on either side of the channel forming source and drain regions. In case of a p-doped transistor body, for example, boron ions are used for dotation. Above the channel, which is covered by an oxide-nitride-oxide layer, a gate electrode is arranged. The nitride layer functions as a charge-trapping layer, sandwiched by the insulating oxide layers, which avoid vertical retention. Two individual bits are stored in physically different areas of the charge-trapping region. The first area is near the source and the second area is near the drain. The bits are programmed by using channel hot electron programming to inject electrons from the channel into the charge-trapping region according to the applied voltages. For erasing a bit, hot holes or Fowler-Nordheim tunneling can be used. The bit can be read by applying a reverse voltage between the source and drain compared to a voltage that is necessary to program the bit.

So called programming and reading voltages, that are applied to the leads of the transistor body for writing, erasing and reading the cell, depend on the width of the channel and the concentration of dopant ions in the transistor body. The deviation of the threshold voltage of the transistor increases with decreasing the width of the channel and non-homogeneity of the dopant ions in the transistor body.

A cell array consists of several cells arranged as a matrix. The minimum distance between two neighboring cells of the cell array is limited by interference effects, especially residual injection into a charge-trapping layer of a neighboring cell due to channel hot electron programming.

It is known that transistors in a transistor array can be separated by isolating areas therebetween preventing interference effects. The isolating area is normally formed by shallow trench isolation (STI) comprising forming a trench in a upper layer of a semiconductor substrate and filling the trench with insulating material. A trench can be formed for example by photolithographic etching.

Shallow trench isolation is applied to separate memory cells in a cell array; but the segregation of dopant ions of the transistor body, near the isolating trench, into the insulating material results in a non-homogeneity of the dopant ions in the transistor body. Another diffusion effect relating to dopant ions is known from boron phosphorous silicate glass (BPSG) wherein the diffusion of ions into a neighboring transistor body is lessened by a diffusion barrier.

Considering an NROM cell array, the effects of segregation vary from cell to cell due to the above-described segregation. Therefore, the operating voltages of the cells in an array vary also, especially in the case of small channel width. But, operating a cell array requires equal driving voltages of each cell otherwise the logic circuit of the array is hard to realize.

### SUMMARY OF THE INVENTION

In one aspect, the invention provides a semiconductor device and a method for fabricating a region thereon that overcomes the above-mentioned disadvantages of the prior art devices.

In a further aspect, the present invention provides a transistor body of doped semiconductor substrate and diffusion barrier forming at least one trench into a top of the semiconductor substrate limiting an isolating area. Preferably, the dopant concentration in the transistor body is homogeneous or nearly homogeneous.

In a first embodiment, a semiconductor device includes a transistor body of doped semiconductor substrate and a conterminous isolating area formed of insulating material. A diffusion barrier is located between the transistor body and the isolating area. The diffusion barrier can form a trench into a top of the semiconductor substrate limiting the isolating area.

In another embodiment, a semiconductor device includes an active area of doped semiconductor substrate and a conterminous isolating area formed of insulating material. A diffusion barrier is located between the active area and the isolating area. The diffusion barrier can form a trench into a top of the semiconductor substrate limiting the isolating area.

A preferred embodiment of the device further includes an active area of boron doped semiconductor substrate and a conterminous oxy-nitride layer forming at least one trench into a top of the semiconductor substrate limiting the isolating area. There can be an oxide layer between the active area and the oxy-nitride layer.

In another aspect, the present invention provides a trench limiting a channel, which is part of an improved NROM cell, and separating the channel of at least one channel of at least one neighboring cell.

In yet a further object aspect, the present invention provides an improved NROM cell with small channel width and increased programming speed and improved 2-bit-separation.

An inventive embodiment for fabricating the semiconductor device is also described. A semiconductor substrate is provided. Dopant ions are implanted into at least a region on top of the semiconductor substrate to form a transistor body. A trench is formed conterminous to the transistor body into the top of the semiconductor substrate. An oxy-nitride layer is deposited on the surface of the trench. The trench is filled with insulating material.

In an alternative method, a trench is formed into a top of a semiconductor substrate. Dopant ions are implanted into at least an upper layer of the substrate conterminous to the trench to form a transistor body. An oxy-nitride layer is deposited on the surface of the trench and the trench is filled with insulating material.

These and other features and advantages of the invention will become apparent from the following brief description of the drawings, detailed description and appended claims and drawings.

This invention is not limited to NROM cells but can also be used in other semiconductor devices comprising a transistor body, to prevent segregation of ions from the transistor body into adjacant regions.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-section of an intermediate product of a preferred method of production after forming trenches into a semiconductor substrate;

FIG. 2 shows the cross-section according to FIG. 1 with an oxy-nitride layer on the surface of the trenches;

FIG. 3 shows the cross-section according to FIG. 2 with an oxide layer between the transistor body and the oxy-nitride layer;

FIG. 4 shows the cross-section according to FIG. 3 after filling and chemical and mechanical polishing;

FIG. 5 shows the cross-section according to FIG. 4 overlaid by an oxide-nitride-oxide layer and a polysilicon layer;

FIG. 6 shows the cross-section according to FIG. 5 without an oxide layer between the transistor body and the oxy-nitride layer; and

FIG. 7 shows the positioning of the trenches according to diffusion areas and transistor bodies for separating NROM cells in the top view.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

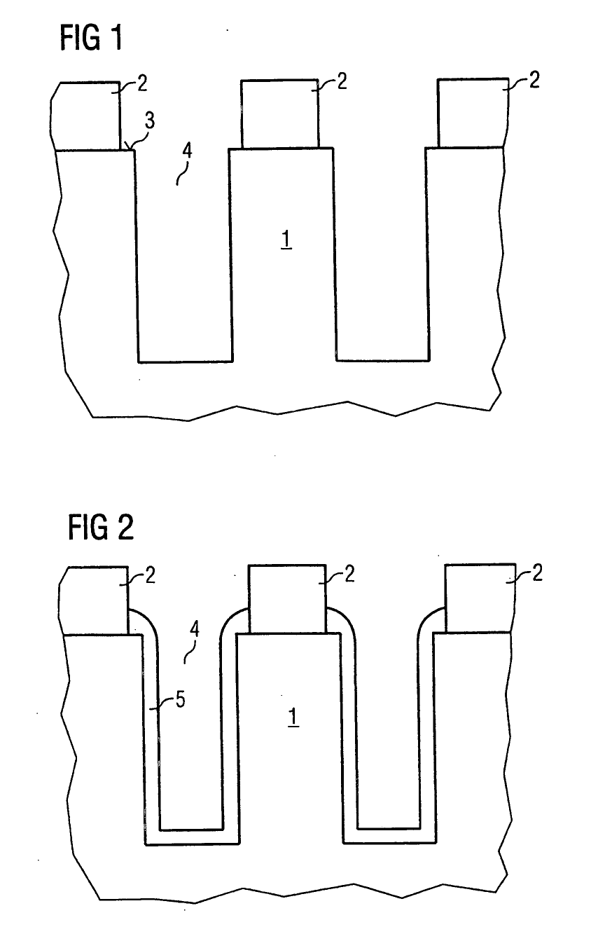

FIG. 1 shows a cross-section of a region of a semiconductor device. After having covered semiconductor material by a nitride layer 2, trenches 4 are formed into a top of the semiconductor substrate. The semiconductor material between the trenches forms a transistor body 1 conterminous with a trench 4 (e.g., the body 1 borders on the trench 4). The transistor body 1 is boron doped. Alternatively, or additionally, boron ions can be implanted before forming the trenches 4 into the semiconductor substrate.

A further pullback step results in laterally removing the nitride. Therefore the pad nitride 2 on the semiconductor material between the trenches is not flush with the edges of the trenches 4. This step exposes an upper surface 3 of the transistor body 1.

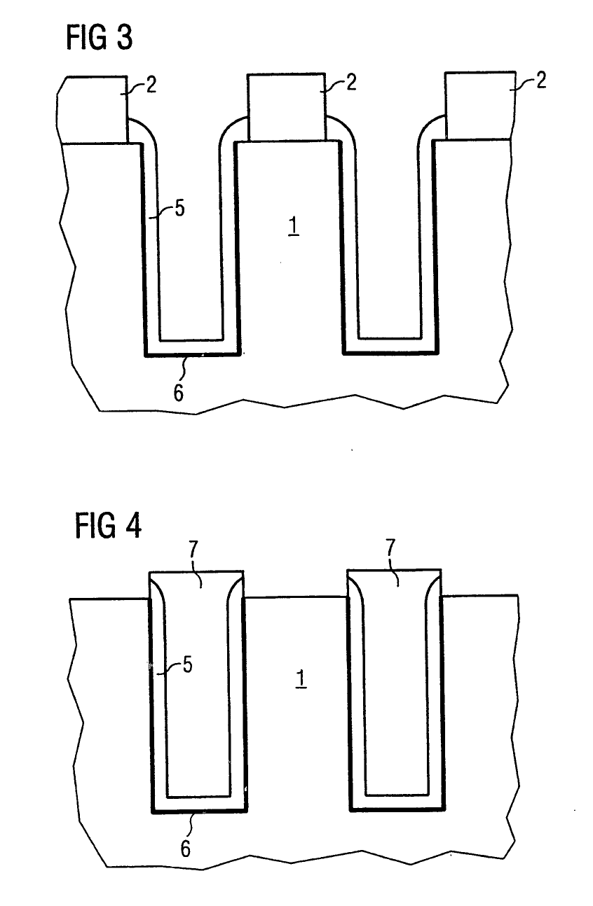

FIG. 2 shows the cross-section according to FIG. 1 after further processing. In particular, an oxy-nitride layer 5 (e.g., SiON) is deposited on the surface of the trench 4. The pullback 3 results in a rounded edge of the oxy-nitride layer 5. The pad nitride 2 prevents covering the transistor body 1 with residual material, which is deposited on the surface of the trench 4, or is deposited into the trench 4. It is not necessary to cover the total surface of the trench. Preferably, the upper region of the trench that limits the channel in the transistor body will be covered.

The oxy-nitride layer 5 prevents segregation of the boron ions of the transistor body 1 into the STI, essentially without negative effect on the data retention, because the number of charge-trays in the oxy-nitride layer is small as compared to a pure nitride layer.

FIG. 3 shows the same semiconductor region according to FIG. 1 after an alternative processing step. An oxide layer 6 is provided between the transistor body 1 and the oxy-nitride layer 5 to prevent mechanical stress, which may result in a defective device. The oxide layer 6 is preferably thermally grown before depositing the oxy-nitride layer 5. Alternatively, the oxide layer 6 can be deposited.

FIG. 4 shows the region according to FIG. 3 after a further processing step. The trench 4 is filled by insulating material 7, for example an oxide such as silicon dioxide. The pad nitride 2 is removed. Mechanical and chemical polishing planarizes the surface of the filled trench. Although in FIG. 4 there is an oxide layer 6 and an oxy-nitride layer 5 between the transistor body 1 and the isolating area 7, it is also possible to provide only an oxy-nitride layer 5 between the transistor body 1 and the isolating area 7 (as was described with respect to FIG. 2).

FIG. 5 shows the region according to FIG. 4 after depositing an oxide layer 8 over the transistor body 1 and overlaying a nitride layer 9 and a further oxide layer 10 over the transistor body and the isolation area. Typical thickness of the nitride layer 9 is about 6-7 nm and typical height of the oxide layer 10 is about 12 nm. The oxide-nitride-oxide layer 8, 9, 10 functions as a charge-trapping layer, above a channel formed by the transistor body 1 in a NROM cell. It is sufficient to cover only the transistor body 1 of the NROM cell with the oxide-nitride-oxide layer. The wordline 11, comprising the gate electrodes on top of the oxide-nitride-oxide layer, is preferably formed by the application and structuring of a polysilicon layer.

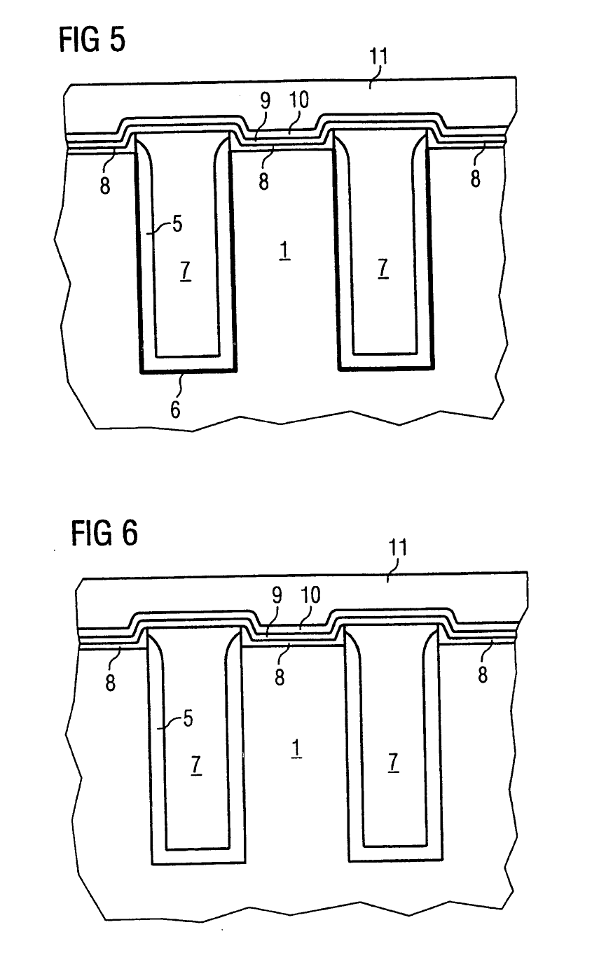

FIG. 6 shows an alternative embodiment in the cross-section according to FIG. 5 without an oxide layer between the transistor body 1 and the oxy-nitride layer 5.

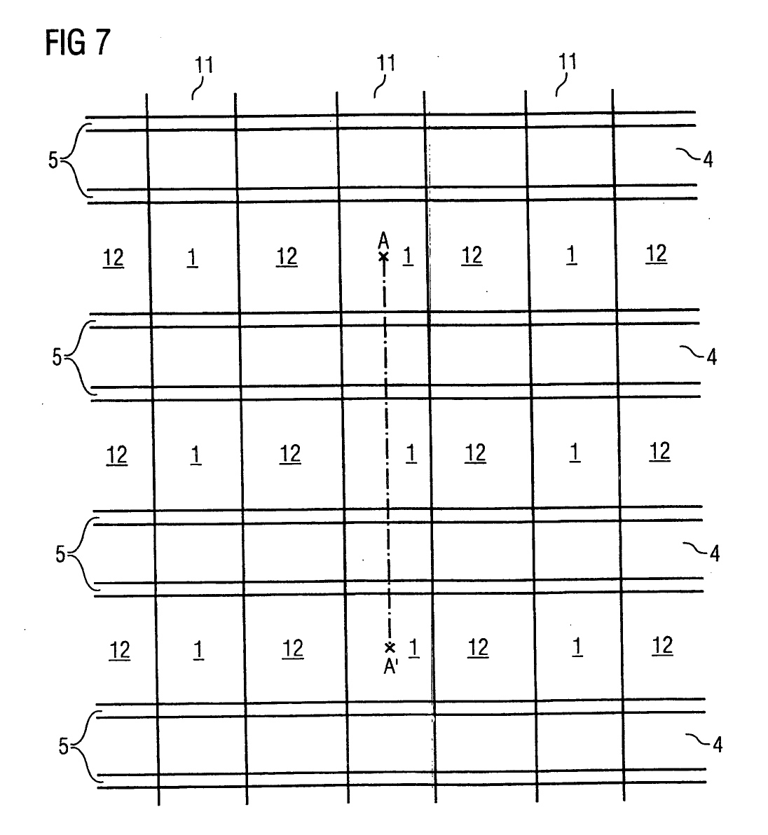

FIG. 7 shows a top view of the position of the trenches and diffusion areas in the substrate for separating cells. Several diffusion areas 12 are provided. A cell includes two opposing areas 12 forming source and drain regions and limiting a transistor body 1 forming a channel therebetween. A trench 4 separates a channel of a cell by a channel of a neighboring cell. The trench 4 is not in the direction of the source and drain regions. Advantageously, the channel is limited by two opposing trenches on each side that are not in the direction of source and drain. The isolating trench 4 prevents interference effects. Therefore, the distance between the cells can be reduced.

The profiles shown in FIGS. 1 to 6 are along the lines between A and A′ shown in FIG. 7.

The above-written preferred production steps also characterize the preferred embodiment of the described transistor body separated by shallow trench isolation.

Although boron is the preferred dopant the present invention is not limited to boron. For example, indium is a possible dopant as well. If n-type dopants are desired, either arsenic or phosphors, as examples, can be used.

What is claimed is:

1. A semiconductor device comprising:
a transistor body comprising a doped portion of a semiconductor substrate;
an isolating area formed of insulating material, the isolating area conterminous with the transistor body; and
an oxy-nitride layer located between said transistor body and said isolating area.

2. The semiconductor device according to claim 1 wherein the oxy-nitride layer is formed on trench walls in a top of said semiconductor substrate, the trench walls limiting said isolating area.

3. The semiconductor device according to claim 1 and further comprising an oxide layer between said transistor body and said oxy-nitride layer.

4. The semiconductor device according to claim 1 wherein a concentration in the transistor body is homogeneous or nearly homogeneous.

5. The semiconductor device according to claim 1 wherein the doped portion of the semiconductor substrate is doped with boron.

6. The semiconductor device according to claim 1 wherein an oxy-nitride layer is formed in at least one trench in a top of said semiconductor substrate adjacent the isolating area, the transistor body forming a channel that is covered by an oxide-nitride-oxide layer.

7. The semiconductor device according to claim 6, and further comprising:
first and second diffusion areas formed within the semiconductor substrate, wherein said channel is located between the first and second diffusion areas;
a second isolating area formed of insulating material and conterminous with the transistor body, wherein the isolating area and the second isolating area comprise a trench located on opposing sides of the transistor body, wherein the isolating area and the second isolating area bound the channel and the first and second diffusion areas.

8. A semiconductor device according to claim 6 wherein said channel is part of an NROM cell and said isolating area separates the channel from at least one channel of at least one neighboring NROM cell.

9. A semiconductor device comprising a transistor body of boron doped in a semiconductor substrate and an oxy-nitride layer formed in at least one trench that is in a top of said semiconductor substrate, the oxy-nitride layer limiting an isolating area that is conterminous with said transistor body.

10. A semiconductor device comprising a transistor body of boron doped semiconductor substrate and an oxy-nitride layer formed in at least one trench in a top of said semiconductor substrate and limiting an isolating area, wherein the boron concentration in the transistor body is homogeneous or nearly homogeneous.

11. A semiconductor device comprising an active area of doped semiconductor substrate and a conterminous isolating area formed of insulating material, wherein an oxy-nitride layer is between said active area and said isolating area.

12. The semiconductor device according to claim 11 wherein the oxy-nitride layer forms trench walls in a top of said semiconductor substrate limiting said isolating area.

13. The semiconductor device according to claim 1 1 and further comprising an oxide layer between said active area and said oxy-nitride layer.

14. The semiconductor device according to claim 11 wherein a dopant concentration in the active area is homogeneous or nearly homogeneous.

15. The semiconductor device according to claim 11 wherein the doped semiconductor substrate comprises a boron doped semiconductor substrate.

16. The semiconductor device according to claim 11, wherein the oxy-nitride layer is formed in at least one trench in a top of said semiconductor substrate, the oxy-nitride layer limiting the isolating area and separating a doped active area forming a channel, the channel being covered by an oxide-nitride-oxide layer.

17. The semiconductor device according to claim 16, wherein said channel is between diffusion areas on either side of said channel, the channel being limited by two isolating areas each formed in a trench on opposing sides of the channel, wherein the trenches of the two isolating areas are not in the direction of said diffusion areas.

18. The semiconductor device according to claim 16 wherein said channel is part of an NROM cell and said isolating area separates the channel from at least one channel of at least one neighboring NROM cell.

19. A semiconductor device comprising:
an active area of boron doped semiconductor substrate;
and an oxy-nitride layer formed in at least one trench in a top of said semiconductor substrate, the oxy-nitride layer limiting an isolating area conterminous with said active area.

20. A semiconductor device comprising:
an active area of boron doped semiconductor substrate; and
an oxy-nitride layer formed in at least one trench in a top of said semiconductor substrate adjacent the active area, wherein the boron concentration in the active area is homogeneous or nearly homogeneous.

21. A semiconductor device comprising:
a semiconductor region;
a trench disposed within the semiconductor region, the trench including a sidewall that abuts an active area in the semiconductor region;
an oxy-nitride layer lining the sidewall of the trench;
an insulating layer filling the trench;
a doped region disposed within the active area of the semiconductor region;
a memory layer sequence overlying the doped region; and
a conductive line overlying the memory layer sequence.

22. The device of claim 21 and further comprising a first heavily doped region and a second heavily doped region, the doped region located between the doped region located between the second heavily doped region and the first heavily doped region.

23. The device of claim 21 wherein the semiconductor device comprises an NROM device.

24. The device of claim 23 wherein the memory layer sequence comprises a composite layer that includes a first oxide layer, a nitride layer overlying the first oxide layer and a second oxide layer overlying the nitride layer.

25. The device of claim 24 wherein the conductive layer comprises a polysilicon layer that overlies and physically touches the second oxide layer.

26. The device of claim 24 wherein the first oxide layer physically contacts the semiconductor of the active area, the nitride layer physically contacts the first oxide layer, the second oxide layer physically contacts the nitride layer and the conductive layer physically contacts the second oxide layer.

27. A method for fabricating an isolating area, the method comprising:
providing a semiconductor substrate;
implanting boron ions into at least a region on top of said semiconductor substrate to form a transistor body;
forming a trench conterminous to said transistor body in the top of said semiconductor substrate;
depositing an oxy-nitride layer on the surface of said trench; and
filling said trench with insulating material.

28. The method of claim 27 wherein the step of implanting boron ions is performed before forming the trench.

29. The method of claim 27 wherein the step of implanting boron ions is performed after forming the trench.

30. The method according to claim 27, and further comprising thermally growing an oxide layer before depositing said oxy-nitride layer.

31. The method according of claim 27, and further comprising:
chemically and mechanically polishing (CMP) an upper surface of the filled trench; and
depositing an oxide-nitride-oxide layer to cover at least said transistor body.

32. A method for fabricating an isolating area, the method comprising:
providing a semiconductor substrate;
implanting boron ions into at least a region on top of said semiconductor substrate to form an active area;
forming a trench conterminous to said active area in the top of said semiconductor substrate;
depositing an oxy-nitride layer on the surface of said trench; and
filling said trench with insulating material.

33. The method according to claim 32, further comprising thermally growing an oxide layer before depositing said oxy-nitride layer.

34. The method according of claim 32, further comprising
chemically and mechanically polishing an upper surface of the filled trench; and
depositing an oxide-nitride-oxide layer to cover at least said active area.

35. A method for fabricating an isolating area, the method comprising:
providing a semiconductor substrate;
forming a trench in a top of said semiconductor substrate;
implanting boron ions into at least top of said substrate conterminous to said trench to form an active area;
depositing an oxy-nitride layer on the surface of said trench; and
filling said trench with insulating material.

36. The method according to claim 35, further comprising thermally growing an oxide layer before depositing said oxy-nitride layer.

37. The method according of claim 35, further comprising
chemically and mechanically polishing an upper surface of the filled trench; and
depositing an oxide-nitride-oxide layer to cover at least said active area.
